(19) United States
(12) Patent Application Publication
(10) Pub. No.: US 2024/0222491 A1
(43) Pub. Date: Jul. 4, 2024

(54) SILICON-CARBIDE-BASED MOSFET DEVICE AND METHOD FOR MANUFACTURING SAME

(71) Applicant: Alkaid-Semi Technologies (Shanghai) Co., Ltd, Shanghai (CN)

(72) Inventors: Kaiyu CHEN, Shanghai (CN); Xiaowen WANG, Shanghai (CN)

(73) Assignee: Alkaid-Semi Technologies (Shanghai) Co., Ltd, Shanghai (CN)

(21) Appl. No.: 18/389,817

(22) Filed: Dec. 20, 2023

(30) Foreign Application Priority Data
Dec. 20, 2022 (CN) 2022116441846

(51) Int. Cl. H01L 29/78; H01L 21/04; H01L 29/06; H01L 29/10; H01L 29/16; H01L 29/66

(52) U.S. Cl. CPC H01L 29/7802; H01L 21/046; H01L 29/0619; H01L 29/1095; H01L 29/1608; H01L 29/66068

(57) ABSTRACT

A SiC-based MOSFET device and a method for manufacturing the same. Layout design of SiC-based MOSFET devices is optimized, which keeps the JFET region while introducing shielding regions extending into the JFET region, thereby retaining the current flow area of the JFET region to a great extent; each shielding region is connected to the respective well region and extends into the JFET region along a diagonal direction of the cellular structure, effectively shielding high electric field regions when the device is reverse biased, and significantly enhancing the device's reliability. The shielding regions and the well regions are simultaneously formed, requiring no additional process, avoiding increase in complexity and cost of manufacturing. This approach achieves low on-resistance and prevents a decrease in reliability caused by the electric field strength at the bottom of the gate oxide layer exceeding a critical breakdown electric field strength of the gate oxide layer.

### CROSS REFERENCE TO RELATED APPLICATION

The present application claims the benefit of priority to Chinese Patent Application No. 202211644184.6, entitled “SILICON-CARBIDE-BASED MOSFET DEVICE AND METHOD FOR MANUFACTURING SAME”, filed with CNIPA on Dec. 20, 2022, the disclosure of which is incorporated herein by reference in its entirety for all purposes.

### FIELD OF THE INVENTION

The present disclosure generally relates to the field of semiconductors, and in particular to a Silicon Carbide (SiC) based Metal Oxide Semiconductor Field Effect Transistor (MOSFET) device and a method for manufacturing the same.

### BACKGROUND OF THE INVENTION

SiC-based MOSFETs have become a popular choice in fields like electric vehicles, charging stations, and data electronics due to their advantages such as high breakdown voltage, high current density, high operating frequency, and good thermal stability.

However, the reliability of SiC-based MOSFETs is a crucial factor that can limit their use in automotive applications. One of the key areas where reliability issues can arise is the junction field-effect transistor (JFET) region, which is located between cells of a SiC-based MOSFET device. Designers often opt for a wider JFET region to achieve a larger current flow area, which results in lower on-resistance. But, reducing the width of the JFET region increases the overall on-resistance of the device, thereby weakening its current carrying capacity. Moreover, the characteristics of the SiO₂—SiC interface can lead to degradation of the gate oxide layer when the device operates under a high electric field for extended periods. The electric field strength inside the gate oxide layer is influenced not only by the interface state density of SiO₂—SiC but also by the width of the vertical channel in the JFET region. In particular, expanding the width of the JFET region results in a higher voltage on the gate oxide layer when the device is in an off state under reverse bias. This can cause the local electric field to exceed the critical breakdown field strength of the gate oxide layer, leading to premature device breakdown and decreased reliability.

Therefore, it is essential to develop a SiC-based MOSFET device with a low on-resistance and a method for manufacturing the same, in order to strike a balance between retaining the current flow area of the JFET region and ensuring the reliability of the device.

### SUMMARY

A first aspect of the present disclosure provides a SiC-based MOSFET device, comprising a semiconductor substrate, which is of a first doping type, and a cellular structure on a first surface of the semiconductor substrate, wherein the cellular structure comprises structural cells arranged in a preset array, wherein the cellular structure comprises:
a drift region, located on the first surface of the semiconductor substrate;
a JFET region and well regions, formed in the drift region, wherein the well regions are of a second doping type, wherein the JFET region and the well regions are laterally adjacent along a top surface of the cellular structure;
source regions, each formed in one of the well regions;
a gate structure, wherein the gate structure comprises a gate oxide layer and a gate electrode located over the gate oxide layer, and the gate oxide layer is formed above the JFET region and partially covers each of the well regions; and
shielding regions, wherein each of the shielding regions is connected to one of the well regions and extends into the JFET region away from the respective well region along a diagonal direction of the cellular structure, an end portion of each of the shielding regions away from the respective source region is of a cylindrical shape extending along a depth direction of the cellular structure, and the shielding regions have a depth and a doping distribution substantially the same as those of the well regions.

A second aspect of the present disclosure provides a method for manufacturing a SiC-based MOSFET device, comprising:
providing a semiconductor substrate, wherein the semiconductor substrate has a first surface and a second surface that are opposite to each other;
forming a drift region and a JFET region defined in the drift region over the semiconductor substrate;
performing ion implantation of a second doping type in the drift region to simultaneously form well regions and shielding regions, wherein the well regions are laterally adjacent to the JFET region, each of the shielding regions extends into the JFET region away from the respective well region along a diagonal direction of a cellular structure of the SiC-based MOSFET device;
performing ion implantation of a first doping type in the well regions to form source regions, wherein an end portion of each of the shielding regions away from a corresponding one of the source regions comprises an arc-shaped surface; and
sequentially forming a gate oxide layer and a gate electrode over the semiconductor substrate.

The present disclosed SiC-based MOSFET device and method for manufacturing the same have the following advantages:

The present disclosure optimizes layout design of SiC-based MOSFET devices, and keeps the JFET region while introducing shielding regions extending into the JFET region, thereby retaining the current flow area of the JFET region to a great extent; each of the shielding regions is connected to the respective well region and extends into the JFET region along a diagonal direction of the cellular structure away from the well region, effectively shielding high electric field regions when the device is reverse biased, and significantly enhancing the device's reliability.

The shielding regions and the well regions are simultaneously formed, which means no additional process is required, thus avoiding an increase in the complexity and cost of manufacturing the device. This approach achieves low on-resistance and prevents a decrease in reliability that could be caused by the electric field strength at the bottom of the gate oxide layer exceeding a critical breakdown electric field strength of the gate oxide layer.

### BRIEF DESCRIPTION OF DRAWINGS

FIG. 1 shows a schematic top view of a JFET region of a reverse-biased SiC-based MOSFET device.

FIG. 2 shows a flowchart illustrating a method for manufacturing a SiC-based MOSFET device according to an embodiment of the present disclosure.

FIG. 3 to FIG. 7 show schematic structural diagrams of intermediate structures obtained after various steps of the method for manufacturing the SiC-based MOSFET device according to an embodiment of the present disclosure, wherein FIG. 4B is a top view of the structure shown in FIG. 4A, FIG. 5B is a top view of the structure shown in FIG. 5A, and FIG. 6B is a top view of the structure shown in FIG. 6A.

FIG. 8 shows a sectional side view of a cellular structure of the SiC-based MOSFET device according to an embodiment of the present disclosure.

FIG. 9 shows a schematic structural diagram of an intermediate structure obtained after forming well regions and shielding regions according to an embodiment of the present disclosure, wherein the cellular structure in the SiC-based MOSFET device is arranged as a hexagonal array.

FIG. 10 shows a schematic structural diagram of the SiC-based MOSFET device in which the cellular structure is arranged as a square array according to an embodiment of the present disclosure.

FIG. 11 shows a schematic structural diagram of the SiC-based MOSFET device in which the cellular structure is arranged as another square array according to an embodiment of the present disclosure.

### REFERENCE NUMERALS

101—Substrate;
200—Epitaxial layer;
201—Drift region;
202—Well region;
203—Source region;
204—Contact region;
2011—Shielding region;
301—Gate oxide layer;
302—Gate electrode layer;
310—Source metal;
410—Drain metal;
2020—Well implantation region;
2021—Shielding region;
3010—Gate oxide;
S1˜S5—Steps.

### DETAILED DESCRIPTION

The following describes the embodiments of the present disclosure through specific examples. A person skilled in the art may easily understand other advantages and effects of the present disclosure from the content disclosed in this specification. The present disclosure may also be implemented or applied through different specific embodiments. Various details in this specification may also be modified or changed based on different viewpoints and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers.

In the context of this disclosure, the structure described with a first feature “on top” of a second feature may include embodiments wherein the first and second features are formed in direct contact, or it may include embodiments wherein additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

Semiconductor related terms used in this specification are technical terms commonly used by professionals in the field of semiconductors. For example, for P-type and N-type impurities, to distinguish their doping concentration, “P+” represents a P-type doping with a high concentration, “P” represents a P-type doping with a medium concentration, “P−” represents a P-type doping with a low concentration, “N+” represents a N-type doping with a high concentration, “N” represents a N-type doping with a medium concentration, and “N−” represents a N-type doping with a low concentration.

“JFET” in this specification is short for Junction Field Effect Transistor.

Herein, a first doping type is a first one of P-type doping and N-type doping, and a second doping type is a second one of P-type doping and N-type doping.

A “semiconductor substrate” as used herein may comprise a variety of semiconductor elements, such as silicon or silicon germanium in a monocrystalline, polycrystalline, or amorphous structure, or may comprise a mixed semiconductor structure made of materials such as silicon carbide, gallium nitride, indium phosphide, gallium arsenide, alloy semiconductors, or combinations thereof.

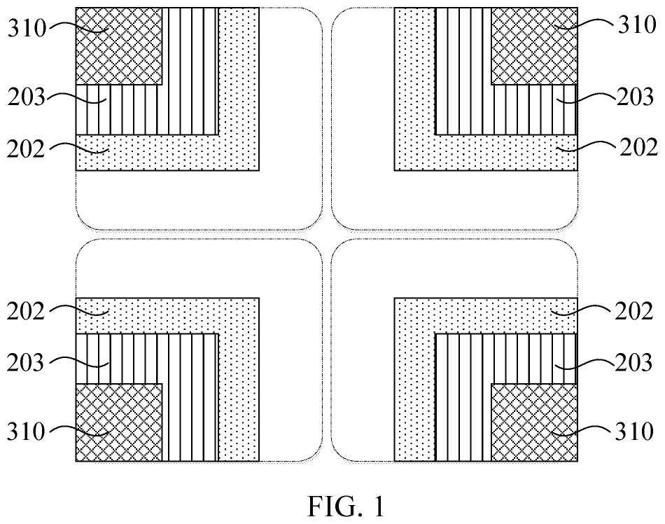

FIG. 1 shows a schematic diagram of a SiC-based MOSFET device in a blocked state. A plurality of structural cells is arranged in an array and share the same JFET region. In other words, the JFET region is the region between the structural cells Regions within the JFET region along diagonals of the cells are local high electric field regions, which are resulted from superimposition of spatial electric field regions in the JFET region. Such superimposition causes the gate oxide layer to bear a higher voltage. Once a critical breakdown field strength of the gate oxide layer is reached, pre-breakdown of the device will occur, reducing reliability of the device.

To improve reliability while achieving a smaller on-resistance, the present disclosure provides a SiC-based MOSFET device and a method for manufacturing the same.

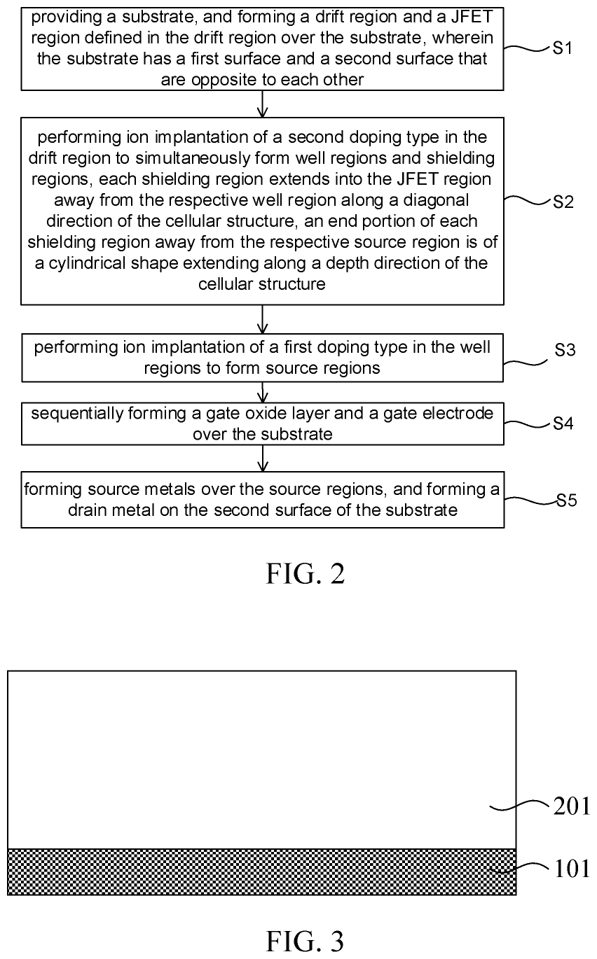

The following describes the method for manufacturing a SiC-based MOSFET device, with reference to FIG. 2 to FIG. 8. The method comprises step S1 to step S5.

First, referring to FIG. 2 and FIG. 3, step S1 comprises: providing a substrate 101, and forming a drift region 201 over the substrate 101.

Specifically, an epitaxial layer 200, which is of a first doping type, is grown on the substrate 101, which is of the first doping type, wherein the substrate 101 may be made of a doped semiconductor material such as silicon (Si), silicon germanium (SiGe), gallium nitride (GaN), or silicon carbide (SiC). As an example, the substrate may be made of N-type 4H-SiC, which may be an N-epitaxial layer.

In some other examples, an N-type substrate may be used directly to form both the substrate and the drift region. The substrate 101 may be a 4-inch wafer, a 6-inch wafer, an 8-inch wafer, or a 12-inch wafer. The size, material, structure, and preparation process of the substrate 101 may be selected according to practical needs.

In step S1, a JFET region is defined on a surface of the drift region 201.

As an example, step S1 also comprises: performing pre-cleaning on a first surface of the semiconductor substrate; and next, defining the JFET region on the first surface of the drift region 201.

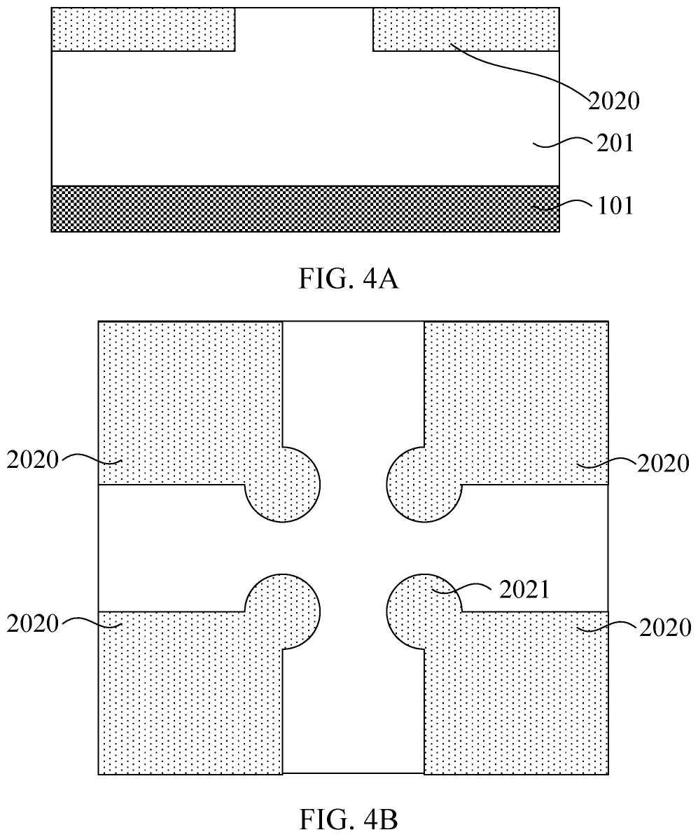

Then, referring to FIG. 4A to FIG. 4B, step S2 comprises: performing ion implantation of a second doping type in the drift region 201 to simultaneously form well regions 202 and shielding regions 2021, wherein each of the shielding regions 2021 extends into the JFET region from the respective well region 202 along a diagonal direction of a cellular structure of the SiC-based MOSFET device, and an end portion of each of the shielding regions 2021 away from a corresponding source region 203 is of a cylindrical shape extending along a depth direction of the cellular structure.

Specifically, in step S2, the step of forming the well regions 202 and the shielding regions 2021 specifically comprises:

S2-1. forming a first implantation barrier layer on the first surface of the semiconductor substrate;

S2-2. patterning the first implantation barrier layer through a photolithography process and an etching process, and defining first pattern regions corresponding to the well regions and the shielding regions in the first implantation barrier layer;

S2-3. performing a plurality of implantations with ions of a second doping type within windows defined by the first pattern regions to form well implantation regions 2020 and the shielding regions 2021; and

S2-4. performing ion activation annealing on the well implantation regions 2020 and the shielding regions 2021, thereby obtaining the well regions 202 and the shielding regions 2021, which have substantially the same depth and doping distribution.

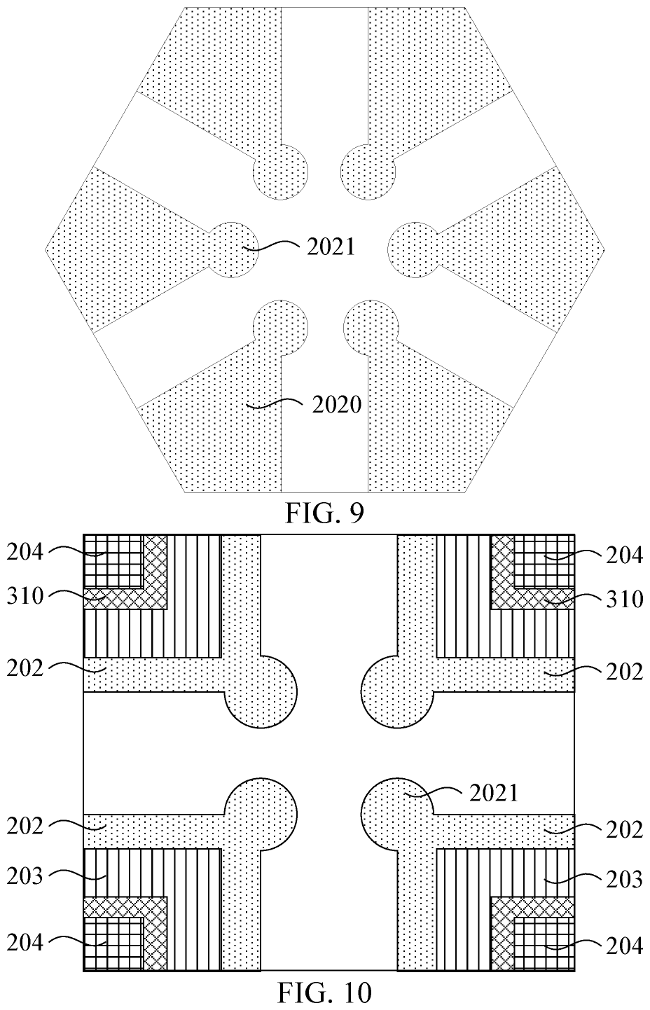

As mentioned above, the SiC-based MOSFET device has a cellular structure; the cellular structure comprises a plurality of structural cells arranged in a preset array. For example, as shown in FIG. 4B and FIG. 9, the structural cells are arranged in a square array or a hexagonal array, and the shielding regions surround end portions of the well regions 202 close to the JFET region and protrude into the JFET region.

Specifically, in step S2-1, a first sacrificial oxide layer, such as a SiO₂ layer, is formed on an N-type epitaxial layer by a low-pressure hot wall chemical vapor deposition method, and the first implantation barrier layer is deposited. The first implantation barrier layer may be an aluminum layer, or an insulating material layer such as a SiO₂ layer and a SiN layer.

As an example, step S2-3 comprises: performing four ion implantations with aluminum ions at an ambient temperature of 650° C., where aluminum ions with implantation energies of 450 keV, 300 keV, 200 keV, and 120 keV are used sequentially, implantation doses of the aluminum ions are respectively 7.97×10¹³ cm⁻², 4.69×10¹³ cm⁻², 3.27×10¹³ cm⁻², and 2.97×10¹³ cm⁻², and the well implantation regions 2020 and shielding regions 2021 obtained thereafter have the same depth and doping distribution; for example, graded doping is adopted, so that regions closer to the gate are lightly doped to ensure stability of breakdown characteristics and threshold voltage, while internal regions are highly doped to reduce on-resistance and reduce the internal temperature of the device.

As an example, step S2-4 comprises: after ion implantation, cleaning the first surface of the semiconductor substrate by using, for example, an RCA cleaning standard, drying the cleaned semiconductor substrate, and then forming a protective film, such as a carbon film, on the first surface; and then, performing ion activation annealing in an argon atmosphere at 1700° C. to 1750° C. for 10 min, where the well regions 202 and the shielding regions 2021 are formed with graded doping.

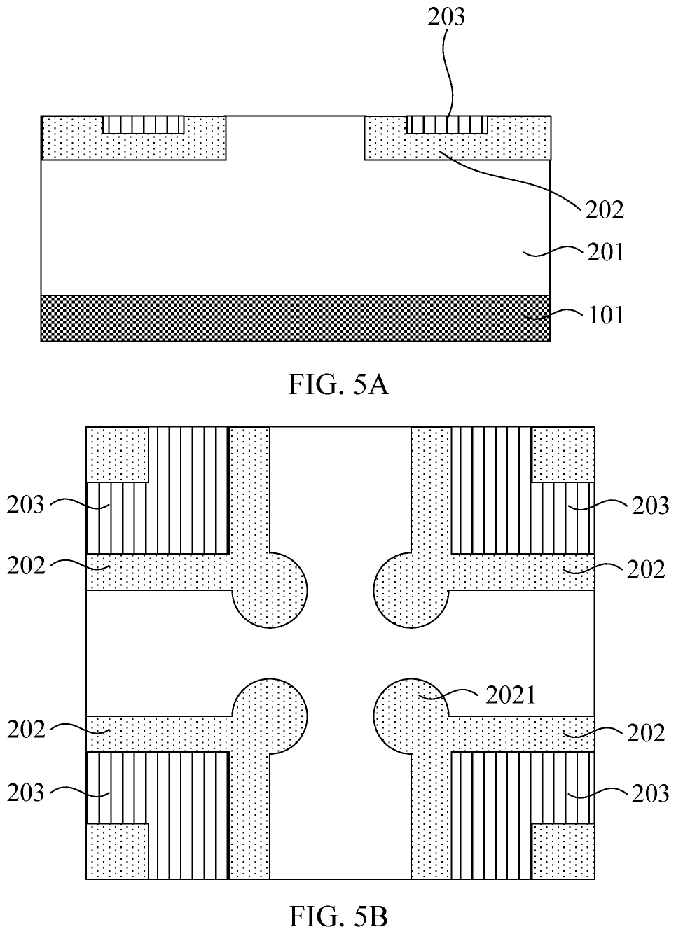

Then, referring to FIG. 5A to FIG. 5B, in step S3, ion implantation of the first doping type is performed in the well regions 202 to form source regions 203. As an example, the first doping type is N-type. For example, Nitrogen ions are used to perform ion implantation in the moderately doped P-type well regions to form heavily doped N-type source regions.

Specifically, step S3 comprises step S3-1: forming a second sacrificial oxide layer and a second implantation barrier layer over the first surface of the semiconductor substrate in a manner similar to that of forming the first sacrificial oxide layer and the first implantation barrier layer in step S2-1. As an example, second pattern regions defined in the second implantation barrier layer serve as implantation windows, and a plurality of implantations are performed with ions of the second doping type to form the source regions. In step S3-1, as an example, two ion implantations are performed in the windows defined by the second pattern regions at an ambient temperature of 650° C., where nitrogen ions with implantation energies of 80 keV and 30 keV are used sequentially, and implantation doses of the nitrogen ions are respectively 3.9×10¹⁴ cm⁻² and 1.88×10¹⁴ cm⁻² to form heavily doped N-type implantation regions.

As an example, step S3-1 further comprises: after ion implantation, cleaning surfaces of the semiconductor substrate by using, for example, an RCA cleaning standard, drying the cleaned semiconductor substrate and then forming a protective film, such as a carbon film; and then, performing ion activation annealing on the heavily doped N-type implantation regions in an argon atmosphere at 1700° C. to 1750° C. for 10 min to form the heavily doped N-type source regions.

As an example, step S3 further comprises step S3-2: performing ion implantation of the second doping type in the well regions 202 to form contact regions 204. As shown in FIG. 5A to FIG. 5B, each of the contact regions 204 is laterally adjacent to one of the source regions 203 along a top surface of the cellular structure; for examples, top surfaces of the contact regions 204 and the source regions 203 are flush; the contact regions 204 are further away from the JFET region than the source regions 203 are from the JFET region. Preferably, the contact regions 204 have a depth greater than that of the well regions 202.

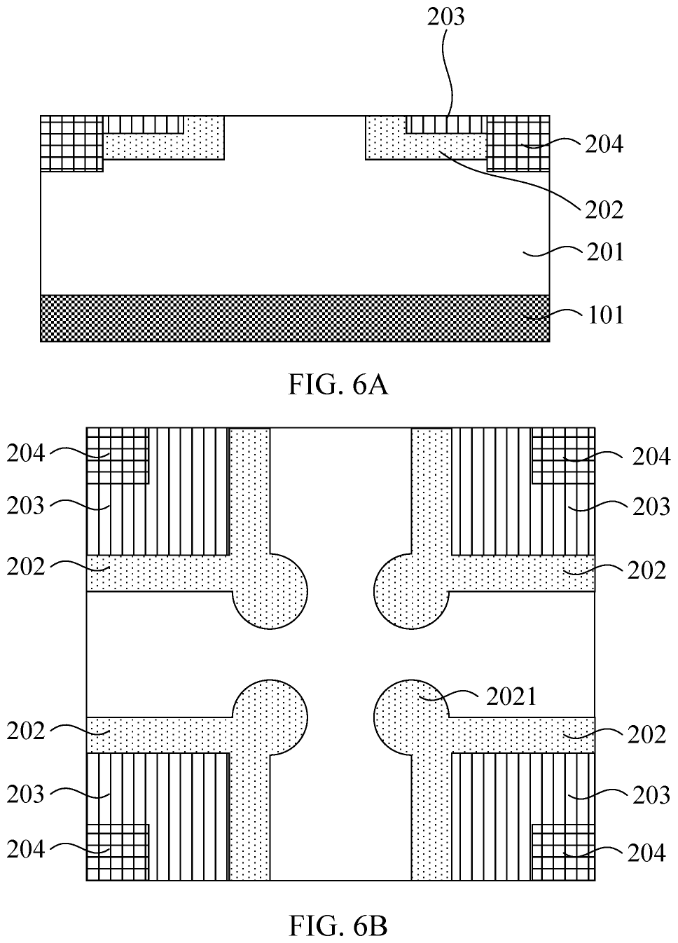

Specifically, as shown in FIG. 6A to FIG. 6B, step S3-2 of forming the contact regions 204 comprises: forming a third sacrificial oxide layer and a third implantation barrier layer over the first surface of the semiconductor substrate in a manner similar to that of forming the first sacrificial oxide layer and the first implantation barrier layer in step S2-1; patterning the implantation barrier layer through a photolithography process and an etching process, and define third pattern regions in the third implantation barrier layer; and performing two aluminum ion implantations in the well regions 202 in windows defined by the third pattern regions at an ambient temperature of 650° C., where aluminum ions with implantation energies of 90 keV and 30 keV are used sequentially, and implantation doses of the aluminum ions are respectively 1.88×10¹⁴ cm⁻² and 3.8×10¹⁴ cm⁻², to form corresponding P+ implantation regions, and each of the P+ implantation region is laterally adjacent to one of the source regions 203 along the top surface of the cellular structure; for examples, top surfaces of the P+ implantation regions and the source regions 203 are flush. In some examples, the structural cells are arranged in a square array, and each of the P+ implantation regions is laterally surrounded by the respective source region 203.

As an example, step S2-3 further comprises: after ion implantation, cleaning surfaces of the semiconductor substrate by using, for example, an RCA cleaning standard, drying the cleaned semiconductor substrate and then forming a protective film, such as a carbon film; and then, performing ion activation annealing in an argon atmosphere at 1700° C. to 1750° C. for 10 min to form heavily doped P-type contact regions 204.

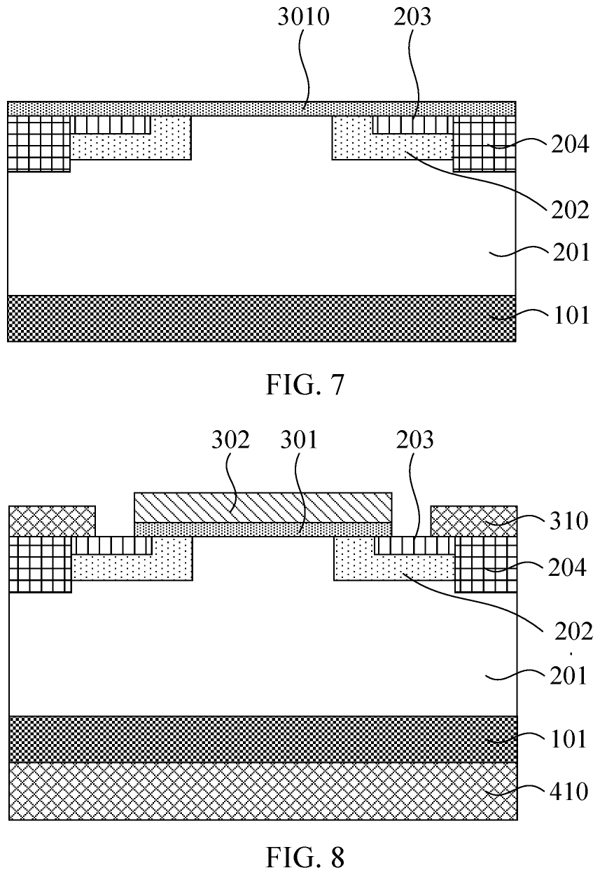

Then, referring to FIG. 7, in step S4, a gate oxide 3010 and polysilicon are sequentially formed over the first surface of the semiconductor substrate; and the gate oxide and the polysilicon are patterned through a photolithography process and an etching process to form a gate oxide layer 301 and a polysilicon gate. As an example, forming the gate oxide layer 301 comprises: performing thermal oxidation on a surface of the epitaxial layer 200, where a material of the gate oxide layer 301 comprises silicon dioxide.

Then, referring to FIG. 8, in step S5, source metals 310 are above the source regions, and a drain metal 410 is formed on a second surface of the semiconductor substrate.

As an example, in step S5, forming the source metal 310 on the surface of the source region 203 comprises: forming the source metals 310, using materials such as such as Ti/Al/Ni, wherein each of the source metals 310 covers one of the contact regions 204 and partially covers a corresponding source region 203 (i.e., the source region that is connected to the contact region) through a magnetron sputtering or electron beam evaporation process; and forming the drain metal 410, using materials such as Ti/Ni, on the second surface of the semiconductor substrate (which is heavily doped with N-type doping) through a magnetron sputtering or electron beam evaporation process.

As an example, step S5 further comprises: after the source metals and the drain metal are formed, performing rapid thermal annealing on the entire semiconductor substrate, for example, at a temperature of 1000° C. for 3 min, so that the source regions 203 and the source metals 310 have ohmic contact formed therebetween to reduce contact resistance and optimize electrical connection characteristics of the electrodes.

As an example, after the step of performing rapid thermal annealing, a metal electrode, such as an aluminum electrode, is deposited on a top surface of the polysilicon gate. It should be noted that, the polysilicon gate may be replaced with a metal gate in some other embodiments, and the metal gate may be formed on the gate oxide layer through a photoresist stripping process after the step of performing rapid thermal annealing.

The present disclosure further provides a SiC-based MOSFET device. The SiC-based MOSFET device may be manufactured by using the foregoing method, but is not limited thereto. As an example, the SiC-based MOSFET device is directly manufactured by using the foregoing manufacturing processes.

The following describes an exemplary structure of the SiC-based MOSFET device with reference to FIG. 8 to FIG. 11.

Referring to FIG. 8 to FIG. 11, the SiC-based MOSFET device comprises a semiconductor substrate and a cellular structure comprising a plurality of structural cells arranged on a first surface of the semiconductor substrate in a preset array, and the cellular structure comprises: a drift region 201, located on the first surface of the semiconductor substrate; a JFET region and well regions 202 that are laterally adjacent along a top surface of the cellular structure and are formed in the drift region 201; shielding regions, formed in the JFET region; source regions 203, arranged in the well regions 202; and a gate structure, where the gate structure comprises a gate oxide layer 301 and a gate electrode 302 formed over the gate oxide layer, and the gate oxide layer 301 is above the JFET region and partially covers each of the well regions. The shielding regions 2021 have the same depth and doping distribution as the well regions 202; each of the shielding regions 2021 is connected to one of the well regions 202 and extends into the JFET region from the respective well region 202 in a diagonal direction of the cellular structure (e.g., the diagonal direction is along a diagonal of the outermost square of FIG. 10, or a diagonal of the hexagon of FIG. 9), and an end portion of each of the shielding regions 2021 away from the respective source region 203 is of a cylindrical shape extending along a depth direction of the cellular structure; the shielding regions serve to partially shield high electric fields on diagonals of the cellular structure, reducing the electric field stress that the gate oxide layer has to bear and avoiding the gate oxide layer causing pre-mature breakdown of the device.

As an example, the semiconductor substrate comprises a heavily doped substrate 101 of a first doping type and a lightly doped epitaxial layer of the first doping type. As an example, the substrate 101 and the epitaxial layer may be made of N-type 4H-SiC.

Specifically, the preset array comprises one or more of a square array, a hexagonal array, and an octagonal array; the adoption of the array increases the number of channels without increasing the device area, further reducing the on-resistance.

For example, the preset array may be a square array or a hexagonal array, that is, the structural cells are arranged in a square array or a hexagonal array; the shielding regions 2021 of the structural cells are respectively connected to the well regions 202 and each of them extends along a diagonal of the cellular structure toward the center of the cellular structure. Since the current flow area of the JFET region is retained to a great extent, the device has a low on-resistance. In addition, with the shielding regions extending along the diagonals of the cellular structure, local high electric field regions can be shielded, improving reliability of the gate oxide layer.

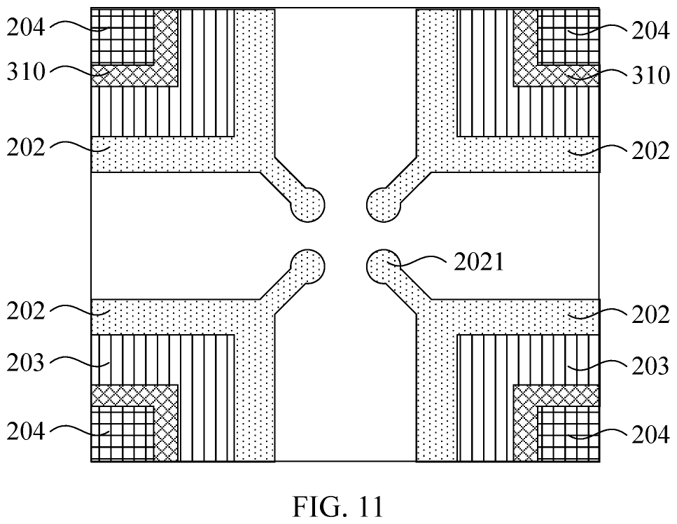

When the preset array is a square array, each of the shielding regions 2021 extends a diagonal direction of the square (i.e., pointing from a vertex of the square to the center of the square), as shown in FIG. 10 to FIG. 11; each of the shielding regions 2021 themselves is of a cylindrical shape extending along a depth direction the cellular structure. Each “cylinder”, that is one shielding region, has an axis overlapping with an apex of the respective well region and has a diameter not exceeding ⅓ of a maximum width of the JFET region, which ensures that there is a sufficient spacing between each two adjacent shielding regions 2021 extending into the same JFET region to avoid an enhanced electric field caused by overlapping depletion regions of the shielding regions 2021 under reverse bias.

In another example, the structural cells are arranged in a square array, and each of the shielding regions further comprises an elongated column section extending along the diagonal direction of the cellular structure, and the end portion (which is a cylindrical section, as discussed above) of each of the shielding regions covers an end surface of the elongated column section away from the corresponding source region. Preferably, the axis of the cylindrical section coincides with a center line of the end surface (i.e., a line bisecting a side of the end surface) of the elongated column section. As an example, a total length of the elongated column section and the cylindrical section of each shielding region 2021 does not exceed ⅓ of the maximum width of the JFET region, which ensures that there is a sufficient spacing between each two adjacent shielding regions 2021 extending into the same JFET region to avoid an enhanced electric field caused by overlapping depletion regions of the shielding regions 2021 under reverse bias.

When the preset array is a hexagonal array, each of the shielding regions extends along a diagonal direction of the hexagon (i.e., pointing from a vertex of the hexagon to the center of the hexagon), as shown in FIG. 9. When reverse biased, spatial electric field regions of the structural cells will expand into the JFET region, strengthening local electric fields along diagonals of the cellular structure. The shielding regions extend along the diagonals of the cellular structure so as to retain the current flow area of the JFET region to a great extent. In addition, the local high electric field regions are shielded at the diagonals of the cellular structure, thereby preventing premature breakdown of the device caused by the bottom of the gate oxide layer being subjected to higher electric field stress.

As an example, the shielding regions 2021 and the well regions 202 may be formed at the same time, and the two have the same doping distribution and depth. For example, the shielding regions 2021 and the well regions 202 may be fixedly doped or doped in a graded manner. As an example, the shielding regions 2021 and the well regions 202 have a doping concentration that gradually increases in an inward direction from a top surface of the N-type epitaxial layer.

As an example, the cellular structure further comprises contact regions 204, which are of a second doping type, wherein each of the contact regions 204 is laterally adjacent to one of the source regions 203 along the top surface of the cellular structure; for examples, top surfaces of the contact regions 204 and the source regions 203 are flush; and the contact regions 204 are further away from the JFET region than the source regions 203 are from the JFET region. As an example, the contact regions 204 have a depth greater than that of the well regions 202, which is beneficial to improving high-temperature performance of the device and improving surge tolerance of the device.

As shown in FIG. 8 and FIG. 10, the cellular structure further comprises source metals 310 and a drain metal 410, where each of the source metals 310 is in contact with one of the source regions 203, and the drain metal 410 is in contact with a second surface of the semiconductor substrate. As an example, each of the source metals 310 may be configured to be in contact with the one of contact regions 204 and the corresponding source region 203 at the same time. For example, each of the source metals 310 may be a Ti/Al/Ni multi-layer, and the drain metal 410 may be a Ti/Ni multi-layer.

As an example, the SiC-based MOSFET device further comprises a source-region ohmic contact layer and a drain-region ohmic contact layer. The source-region ohmic contact layer is located over the source regions 203 and the contact regions 204, and below the source metals 310. The drain-region ohmic contact layer is formed on a surface of the drain metal 410 facing away from the cellular structure.

As an example, a metal electrode, such as an aluminum electrode, is further formed on a top surface of the polysilicon gate.

As an example, the SiC-based MOSFET may be an N-type MOSFET or a P-type MOSFET.

In summary, the present disclosed SiC-based MOSFET device and method for manufacturing the same have the following advantages:

The present disclosure optimizes layout design of SiC-based MOSFET devices, and keeps the JFET region while introducing shielding regions extending into the JFET region, thereby retaining the current flow area of the JFET region to a great extent; each of the shielding regions is connected to the respective well region and extends into the JFET region along a diagonal direction of the cellular structure away from the well region, effectively shielding high electric field regions when the device is reverse biased, and significantly enhancing the device's reliability.

The shielding regions and the well regions are simultaneously formed, which means no additional process is required, thus avoiding an increase in the complexity and cost of manufacturing the device. This approach achieves low on-resistance and prevents a decrease in reliability that could be caused by the electric field strength at the bottom of the gate oxide layer exceeding a critical breakdown electric field strength of the gate oxide layer.

The foregoing embodiments only exemplarily illustrate the principle and effects of the present disclosure, and are not used to restrict the present disclosure. Anyone familiar with this technology can modify or change the above-mentioned embodiments without departing from the spirit and scope of the present disclosure. Therefore, all equivalent modifications or changes made by those with ordinary knowledge in the technical field without departing from the spirit and technical ideas disclosed in the present disclosure should still be covered by the claims of the present disclosure.

1. A SiC-based MOSFET device, comprising a semiconductor substrate, which is of a first doping type, and a cellular structure on a first surface of the semiconductor substrate, wherein the cellular structure comprises structural cells arranged in a preset array, wherein the cellular structure comprises:
a drift region, located on the first surface of the semiconductor substrate;
a JFET region and well regions, formed in the drift region, wherein the well regions are of a second doping type, wherein the JFET region and the well regions are laterally adjacent along a top surface of the cellular structure;
source regions, each formed in one of the well regions;
a gate structure, wherein the gate structure comprises a gate oxide layer and a gate electrode located over the gate oxide layer, and the gate oxide layer is formed above the JFET region and partially covers each of the well regions; and
shielding regions, wherein each of the shielding regions is connected to one of the well regions and extends into the JFET region away from the respective well region along a diagonal direction of the cellular structure, an end portion of each of the shielding regions away from the respective source region is of a cylindrical shape extending along a depth direction of the cellular structure, and the shielding regions have a depth and a doping distribution substantially the same as those of the well regions.

2. The SiC-based MOSFET device according to claim 1, wherein the preset array comprises one or more of a square array, a hexagonal array, and an octagonal array.

3. The SiC-based MOSFET device according to claim 2, wherein the structural cells are arranged in the square array, each of the shielding regions themselves is of the cylindrical shape extending along the depth direction of the cellular structure, and a cylindrical diameter of each of the shielding region does not exceed ⅓ of a maximum width of the JFET region.

4. The SiC-based MOSFET device according to claim 2, wherein the structural cells are arranged in the square array, each of the shielding regions further comprises an elongated column section extending along the diagonal direction of the cellular structure, wherein the end portion of each of the shielding regions covers an end surface of the elongated column section, and a total lateral length of each of the shielding regions along the top surface of the cellular structure does not exceed ⅓ of the maximum width of the JFET region.

5. The SiC-based MOSFET device according to claim 1, wherein the cellular structure further comprises contact regions, which are of the second doping type, wherein each of the contact regions is laterally adjacent to one of the source regions along the top surface of the cellular structure, wherein the contact regions are further away from the JFET region than the source regions are from the JFET region, and a depth of the contact regions is greater than a depth of the well regions.

6. The SiC-based MOSFET device according to claim 5, wherein the semiconductor substrate comprises a heavily doped substrate of the first doping type and a lightly doped epitaxial layer of the first doping type, and the SiC-based MOSFET device further comprises: source metals and a drain metal, wherein each of the source metals is in contact with one of the contact regions and the corresponding source region, and the drain metal is in contact with a second surface of the semiconductor substrate away from the lightly doped epitaxial layer.

7. A method for manufacturing a SiC-based MOSFET device, comprising:
providing a semiconductor substrate, wherein the semiconductor substrate has a first surface and a second surface that are opposite to each other;
forming a drift region and a JFET region defined in the drift region over the semiconductor substrate;
performing ion implantation of a second doping type in the drift region to simultaneously form well regions and shielding regions, wherein the well regions are laterally adjacent to the JFET region, each of the shielding regions extends into the JFET region away from the respective well region along a diagonal direction of a cellular structure of the SiC-based MOSFET device;
performing ion implantation of a first doping type in the well regions to form source regions, wherein an end portion of each of the shielding regions away from a corresponding one of the source regions comprises an arc-shaped surface; and
sequentially forming a gate oxide layer and a gate electrode over the semiconductor substrate.

8. The method according to claim 7, further comprising:
performing ion implantation of a second doping type in the well regions to form contact regions, wherein each of the contact regions is laterally adjacent to one of the source regions along a top surface of the cellular structure, wherein the contact regions are further away from the JFET region than the source regions are from the JFET region;
performing pre-cleaning on the first surface of the semiconductor substrate; and
forming a protective film on the first surface of the semiconductor substrate, and performing ion activation annealing in an argon atmosphere at a temperature of 1700° ° C. to 1750° C.

9. The method according to claim 7, further comprising: forming source metals over the source regions, and forming a drain metal on the second surface of the semiconductor substrate, wherein the semiconductor substrate comprises a heavily doped substrate of the first doping type and a lightly doped epitaxial layer of the first doping type.

10. The method according to claim 7, wherein forming the gate oxide layer comprises: performing thermal oxidation on a surface of the epitaxial layer, wherein the heavily doped substrate and the lightly doped epitaxial layer are made of 4H-SiC.
